(19) United States
(12) Patent Application Publication
(10) Pub. No.: US 2011/0224839 A1
(43) Pub. Date: Sep. 15, 2011

(54) Power Point Tracking

(76) Inventor: Christopher Thompson, Narragansett, RI (US)

(21) Appl. No.: 12/722,163

(22) Filed: Mar. 11, 2010

(51) Int. Cl. G06F 1/28; H01L 31/042; G06G 7/63

(52) U.S. Cl. 700/297; 136/244; 703/18

(57) ABSTRACT

An maximum power point tracking unit used in a solar cell power system can find maximum power point more efficiently.

### TECHNICAL FIELD

This invention relates to a maximum power point tracking used in a solar cell power system.

### BACKGROUND

Maximum power point tracking (MPPT) is a technique that varies the DC operating point of the photovoltaic modules so that the photovoltaic modules are able to deliver maximum available power.

### DESCRIPTION OF DRAWINGS

FIG. 1 is a block diagram illustrating the solar power system including an MPPT unit.

FIG. 2 is a flow chart of the MPP calculation and control process used in the MPPT unit shown in FIG. 1.

### DETAILED DESCRIPTION

A maximum power point tracker (MPPT) is a device that functions as an optimal electrical load for a photovoltaic (PV) module. MPPT can operate a module at a voltage that results in the highest possible power output. PV modules have a dynamic operating point where the values of the current (I) and Voltage (V) of the cell result in a maximum power output. This point is dynamic because the solar irradiance that stimulates the module is dynamic due to changing ambient temperature, cloud activity etc. A PV module has an exponential relationship between current and voltage, and the maximum power point (MPP) occurs at the knee of the curve. Maximum power point trackers utilize some type of control circuit or logic to search for this point and thus to allow the converter circuit to extract the maximum power available from a cell. Grid-tied PV inverters utilize MPPT to extract the maximum power from a PV array, convert this to alternating current (AC) and sell energy to the operators of the power grid. The benefits of MPPT are typically greatest during periods of rapidly changing weather conditions such as fast moving clouds or rising/falling temperatures. Presently almost all PV inverters available on the market offer solutions with an embedded MPPT for the PV panels that are connected to it. Because there are different PV panels available, the inverter vendors develop MPPT algorithms that are compatible with almost all of these panel options. In implementing MPPT, inverters search a range of voltages to find which voltage results in the panel producing the most power. When the inverter spends time searching for the MPP, it is by definition not operating at the MPP. However, if the inverter does not search thoroughly for the MPP, it may not find the ideal operating voltage to maximize power. Therefore, MPPT algorithms are trying to not only find the best MPP but to find the MPP as quickly as possible.

If the inverter is working with a known type of PV Panel, it is possible to optimize the MPPT algorithm to assist in finding the best MPP in an extremely quick fashion. In most installations, temperature and irradiance measurements are made with local sensors. By using known operating parameters of the panels in conjunction with temperature and irradiance conditions, the MPP of the panel can be estimated with high accuracy. In addition, these calculations can be made without the MPPT algorithm going into a search mode where it starts searching for the MPP. As the PV array continues operating, the sensors will continue to collect ambient condition data and therefore new MPPs can be calculated without the inverter having to search for it. This results in not only an accurate MPPT approach but an approach that finds the ideal condition without needing to waste time searching for it.

A method to optimize maximum power point tracking efficiency of a photovoltaic module-based power system can include measuring ambient temperature and irradiance conditions proximate to the photovoltaic module-based power system. The photovoltaic module-based power system can have a set of operating parameters. The operating parameters can include operating parameters for the photovoltaic modules in the system. The operating parameters can include one or more curves defining an optimal DC operating voltage as a function of temperature and/or irradiance. The method can include determining a maximum power point based on the operating parameters of the photovoltaic module and temperature and irradiance conditions. The MPP is now capable of being determined without searching for an optimized power point. The method can include adjusting the DC operating point of the photovoltaic module-based power system to the maximum power point by optimizing the DC operating voltage. The method can include collecting and sending temperature and irradiance measurement data to a power network operation center by a data collecting system. The method can include storing temperature and irradiance measurement data in a database. The method can include using an existing environmental temperature and irradiance database to determine the maximum power point. The method can include using a set of known operating data about the modules to determine the maximum power point.

The method can further include measuring the operating point of the photovoltaic module-based power system by a power meter and, as the power system continues operating, measuring real time temperature and irradiance conditions of the photovoltaic module-based power system. The method can include correlating the operating parameters of the photovoltaic module to temperature and irradiance conditions to determine the maximum power point. The method can include adjusting the operating point of the photovoltaic module-based power system to the maximum power point instantaneously. The data collecting system can include a photovoltaic module temperature sensor. The system can include an ambient irradiance sensor. The system can include a remote terminal unit connecting to the sensors, and converting sensor signals to digital data and sending digital data to the power network operation center. The system can include a human-machine interface connecting to the remote terminal unit.

A maximum power point tracking device of a photovoltaic module-based power system can have a DC operating point and a set of parameters. The operating parameters can include operating parameters for the photovoltaic modules in the system. The operating parameters can include one or more curves defining an optimal DC operating voltage as a function of temperature and/or irradiance. The maximum power point tracking device can include a temperature sensor and an irradiance sensor. The maximum power point tracking device can include a power meter measuring the operating point of the photovoltaic module-based power system, as the power system continues operating, a data module storing a set of known module operating data, an analysis module to determine the maximum power point based on a measured temperature, a measured irradiance, and known module operating data, and a control module adjusting the operating point of the photovoltaic module-based power system to the maximum power point by optimizing the DC operating voltage.

The maximum power point tracking device can include a data collecting system to collect and send temperature and irradiance measurement data to a power network operation center. The maximum power point tracking device can include a database to store temperature and irradiance measurement data. The maximum power point tracking device can include an existing environmental temperature and irradiance database to determine the maximum power point. The data collecting system can include a remote terminal unit connecting to the sensors, converting sensor signals to digital data and sending digital data to the power network operation center, and a human-machine interface connecting to the remote terminal unit.

A photovoltaic module-based power system can include a photovoltaic array can have a DC operating point and a set of operating parameters. The operating parameters can include operating parameters for the photovoltaic modules in the system. The operating parameters can include one or more curves defining an optimal DC operating voltage as a function of temperature and/or irradiance. The photovoltaic module-based power system can include a maximum power point tracking unit which can determine the DC operating point and can be electrically connected to the photovoltaic array. The maximum power point tracking unit can include a temperature sensor, an irradiance sensor, a power meter measuring the DC operating point of the photovoltaic module-based power system, as the power system continues operating, a data module storing a set of known module operating data, an analysis module to determine the maximum power point based on a measured temperature, a measured irradiance, and known module operating data, and a control module adjusting the DC operating point of the photovoltaic module-based power system to the maximum power point by optimizing the DC operating voltage.

The photovoltaic module-based power system can include a data collecting system to collect and send temperature and irradiance measurement data to a power network operation center. The photovoltaic module-based power system can include a database to store temperature and irradiance measurement data. The photovoltaic module-based power system can include an existing environmental temperature and irradiance database to determine the maximum power point. The data collecting system can include a remote terminal unit connecting to the sensors, converting sensor signals to digital data and sending digital data to the power network operation center, and a human-machine interface connecting to the remote terminal unit.

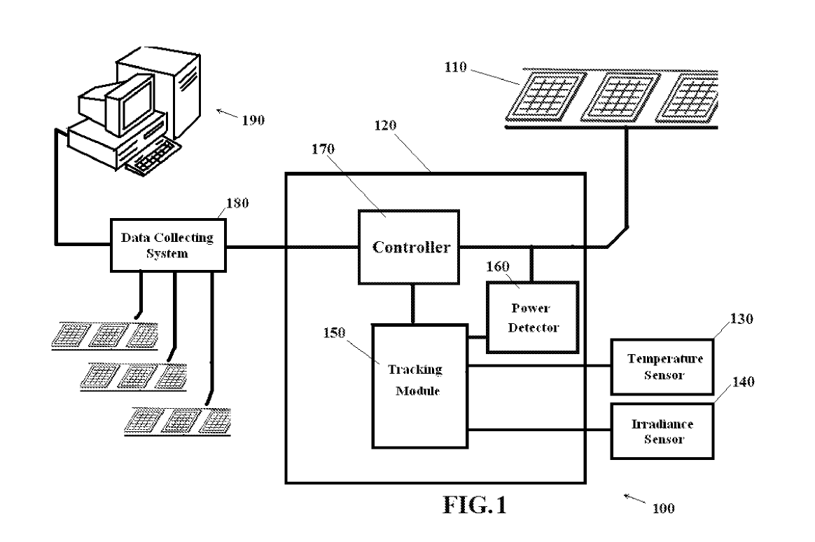

Referring to FIG. 1, solar power system 100 can include photovoltaic or solar array 110. Solar modules 110 can be arranged in any suitable manner, for example, in arrays positioned on the ground or on rooftops. Solar array 110 can include any suitable photovoltaic devices, including thin-film solar devices such as cadmium telluride (CdTe) or copper indium gallium selenide (CIGS). Alternatively, the photovoltaic devices can be crystalline silicon solar devices or any other suitable photovoltaic devices capable of generating direct current electricity. Photovoltaic array 110 can be connected to MPPT unit 120. MPPT unit 120 can include temperature sensor 130 and irradiance sensor 140 to measure ambient conditions. The temperature sensor could be measuring the ambient temperature or the module temperature. MPPT unit 120 can also include tracking module 150 using the operating parameters of the photovoltaic module and temperature and irradiance conditions to determine the maximum power point. MPPT unit 120 can further include power meter 160 measuring the current operating point of solar power system 100, as system continues operating. Power meter 160 can include input voltage and current sensor to real time monitor the operating point. MPPT unit 120 can include control module 170 adjusting the operating point of solar power system 100 to the maximum power point. MPPT unit 120 can include a maximum power point tracking algorithm to determine the maximum power point.

Solar power system 100 can further include data collecting system 180 to collect and send temperature and irradiance measurement data to power network operation center 190. Power network operation center 190 can have a database to store temperature and irradiance measurement data. Power network operation center 190 can have an existing environmental temperature and irradiance database to determine the maximum power point. Data collecting system 180 can include a remote terminal unit connecting to the sensors, converting sensor signals to digital data and sending digital data to the power network operation center, a human-machine interface connecting to the remote terminal unit, or any suitable telecommunication infrastructure.

In some embodiments, the implementation can be done by data collection system 180 connected to a plurality of arrays. For example, sensors can be installed at different solar array sites and the ambient condition measurement data can be sent back to network operation center 190 and stored in a database. Using computers back in the network operation center 190, the irradiance and temperature data can be correlated with operating parameter data of each array. Using these data sets, the maximum power point of each array can be determined and commands can be sent to their individual inverter from network operation center 190. The data can be collected about every second so this control process can be done in real time. An inverter used in solar power system 100 can include any suitable apparatus or combination which can convert DC current from a photovoltaic array to AC current. The inverter can include any suitable mechanical device, electromechanical device, electrical or electronic device, or any suitable combination thereof. The inverter can include a modified sine wave inverter. The inverter can include a pure sine wave inverter. The inverter can include a generator, alternator, or motor, or any suitable combination thereof. The inverter can include a solid-state inverter.

Data collecting system 180 can include supervisory control and data acquisition (SCADA) system or other remote control module, wherein supervisory control and data acquisition (SCADA) system or other remote control module can include at least one sensor acquiring operating data of the solar cell power system, a current/voltage control unit, a computer supervisory system acquiring data from the sensor and sending commands to the current/voltage control unit, a remote terminal unit (RTU) connecting to the sensor in the process, converting sensor signals to digital data and sending digital data to the supervisory system, and a human-machine interface connecting to the remote terminal unit. Solar power system 100 can further include a ground fault circuit interrupter (GFCI).

In some embodiments, grid-tied PV inverters utilize MPPTs to extract the maximum power from a PV array, convert this to alternating current (AC) and sell excess energy back to the operators of the power grid. In other embodiments, Off-grid power systems also use MPPT charge controllers to extract the maximum power from a PV array. When the immediate power requirements for other devices plugged into the power system are less than the power currently available, the MPPT stores the “extra” energy—energy that is not immediately consumed during the day—in batteries. When other devices plugged into the power system require more power than is currently available from the PV array, the inverter drains energy from those batteries in order to make up for the lack of available photovoltaic power.

The output characteristic of a photovoltaic array is nonlinear and changes with solar irradiation and the cell's temperature. Therefore, MPPT technique is needed to draw peak power from the solar array to maximize the produced energy. Maximum power point trackers utilize some type of control circuit or logic to search for this point and thus to allow the converter circuit to extract the maximum power available from a cell. When the inverter spends time searching for the MPP, it is by definition not operating at the MPP. With ambient temperature and irradiance measurements that are made by local sensors, the MPP can be calculated by using known operating parameters of the panels in conjunction with the temperature and irradiance conditions. It can further real time monitor the ambient conditions and make the adjustment to the array's operating point instantaneously.

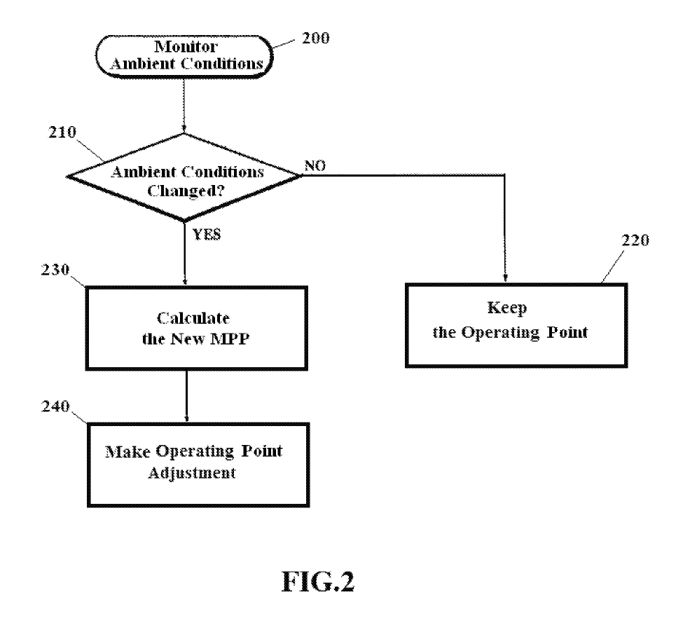

Referring to FIG. 2, in practice, MPPT unit 120 can use control module 170 to adjust the array's operating point. MPPT unit 120 could continually monitor the ambient conditions, such as panel temperature and local irradiance. When the conditions change, MPPT unit 120 could annunciate that it was now necessary to make the adjustment and update the operating point of the solar power system 100. At step 200, the ambient conditions can be monitored. If the ambient conditions changed at step 210 (YES), the new MPP can be quickly estimated at step 230. The operating parameters of solar power system 100 can be used to determine the MPP without involving any searching mode. After the new MPP is determined, the adjustment can be made to change the operating point of solar power system 100 to the new MPP at step 240. To the contrary, if ambient conditions remain the same at step 210 (NO), no adjustment can be made to the solar power system 100 and the operating point can be kept at step 220. This technology is applicable to all solar power system. The benefit of an MPPT unit can be great, especially during rapidly changing weather conditions.

A number of embodiments of the invention have been described. Nevertheless, it will be understood that various modifications may be made without departing from the spirit and scope of the invention. It should also be understood that the appended drawings are not necessarily to scale, presenting a somewhat simplified representation of various preferred features illustrative of the basic principles of the invention.

What is claimed is:

1. A method to optimize maximum power point tracking efficiency of a photovoltaic module-based power system, comprising:
measuring ambient temperature and irradiance conditions proximate to the photovoltaic module-based power system, wherein the photovoltaic module-based power system comprises at least one operating parameter; and
determining a maximum power point based on the at least one operating parameter of the photovoltaic module and the temperature and irradiance conditions, wherein the maximum power point is capable of being determined without adjusting the DC voltage to search for the maximum power point.

2. The method of claim 1, wherein the operating parameter comprises an optimal DC operating voltage that is a function of temperature and irradiance.

3. The method of claim 1, further comprising collecting and sending temperature and irradiance measurement data to a power network operation center by a data collecting system.

4. The method of claim 1, further comprising storing temperature and irradiance measurement data in a database.

5. The method of claim 1, further comprising using an existing environmental temperature and irradiance database to determine the maximum power point.

6. The method of claim 1, further comprising using a set of known operating data about the modules to determine the maximum power point.

7. The method of claim 1, further comprising
measuring the operating point of the photovoltaic module-based power system by a power meter, as the power system continues operating;
measuring real time temperature and irradiance conditions of the photovoltaic module-based power system;
correlating the operating parameters of the photovoltaic module to temperature and irradiance conditions to determine the maximum power point; and
adjusting the operating point of the photovoltaic module-based power system to the maximum power point instantaneously.

8. The method of claim 3, wherein the data collecting system comprises:
a photovoltaic module temperature sensor;
an ambient irradiance sensor;
a remote terminal unit connecting to the sensors, converting sensor signals to digital data and sending digital data to the power network operation center; and
a human-machine interface connecting to the remote terminal unit.

9. A maximum power point tracking device of a photovoltaic module-based power system comprising:
a temperature sensor;
an irradiance sensor;
a power meter measuring the operating point of the photovoltaic module-based power system, as the power system continues operating;
a data module storing a set of known module operating data, wherein the operating data comprise a set of optimal DC operating voltages defined as a function of temperature and irradiance;
an analysis module to determine the maximum power point based on a measured temperature, a measured irradiance, and known module operating data; and
a control module adjusting the operating point of the photovoltaic module-based power system to the maximum power point by optimizing the DC operating voltage.

10. The maximum power point tracking device of claim 9, further comprising a data collecting system to collect and send temperature and irradiance measurement data to a power network operation center.

11. The maximum power point tracking device of claim 9, further comprising a database to store temperature and irradiance measurement data.

12. The maximum power point tracking device of claim 9, further comprising an existing environmental temperature and irradiance database to determine the maximum power point.

13. The maximum power point tracking device of claim 10, wherein the data collecting system comprises:
a remote terminal unit connecting to the sensors, converting sensor signals to digital data and sending digital data to the power network operation center; and
a human-machine interface connecting to the remote terminal unit.

14. A photovoltaic module-based power system comprising:
a photovoltaic array having a DC operating point and a set of operating parameters, including a DC operating voltage; and
a maximum power point tracking unit electrically connected to the photovoltaic array comprising:
a temperature sensor;
an irradiance sensor;
a power meter measuring the DC operating point of the photovoltaic module-based power system, as the power system continues operating;
a data module storing a set of known module operating data, wherein the operating data comprise a set of optimal DC operating voltages defined as a function of temperature and irradiance;
an analysis module to determine the maximum power point based on a measured temperature, a measured irradiance, and known module operating data; and
a control module adjusting the DC operating point of the photovoltaic module-based power system to the maximum power point.

15. The photovoltaic module-based power system of claim 14, further comprising a data collecting system to collect and send temperature and irradiance measurement data to a power network operation center.

16. The photovoltaic module-based power system of claim 14, further comprising a database to store temperature and irradiance measurement data.

17. The photovoltaic module-based power system of claim 14, further comprising an existing environmental temperature and irradiance database to determine the maximum power point.

18. The photovoltaic module-based power system of claim 14, wherein the data collecting system comprises:
a remote terminal unit connecting to the sensors, converting sensor signals to digital data and sending digital data to the power network operation center; and
a human-machine interface connecting to the remote terminal unit.
